(19) United States
(12) Patent Application Publication
(10) Pub. No.: US 2024/0405503 A1
(43) Pub. Date: Dec. 5, 2024

(54) INJECTION-LOCKED LASER-BASED BEATNOTE GENERATION PHASE LOCKED TO REFERENCE

(71) Applicant: Raytheon Company, Waltham, MA (US)

(72) Inventor: Joseph M. Fridlander, San Diego, CA (US)

(21) Appl. No.: 18/327,207

(22) Filed: Jun. 1, 2023

(51) Int. Cl. H01S 3/10; H01S 3/00; H01S 3/13

(52) U.S. Cl. CPC H01S 3/10092; H01S 3/0085; H01S 3/1305; H01S 3/1307

(57) ABSTRACT

An apparatus includes a seed laser configured to generate a seed signal and a modulator configured to modulate the seed signal and generate multiple sideband signals. The apparatus also includes multiple injection-locked lasers configured to generate multiple optical signals based on different ones of the sideband signals. The apparatus further includes a combiner configured to combine the optical signals and generate a combined optical signal. In addition, the apparatus includes a feedback loop configured to modify frequencies of the sideband signals generated by the modulator so that the optical signals generated by the injection-locked lasers have a desired frequency difference. The feedback loop may be configured to perform photonic down-conversion of a portion of the combined optical signal prior to photodetection in order to decrease a frequency of a signal that undergoes photodetection.

### GOVERNMENT RIGHTS

This invention was made with government support under contract number FA8650-21-C-7031 awarded by the U.S. Defense Advanced Research Projects Agency (DARPA). The government has certain rights in the invention.

### TECHNICAL FIELD

This disclosure is generally directed to laser systems. More specifically, this disclosure is directed to injection-locked laser-based beatnote generation that is phase locked to a reference.

### BACKGROUND

Various systems rely on optical combs to perform one or more optical functions within the systems. An optical comb refers to a collection of optical signals having a substantially equal separation or other desired separation in terms of frequency. For example, an optical comb may include multiple optical signals that have a spacing of approximately 100 GHz. Optical combs are useful in a number of signal processing applications or other applications, but sustaining optical comb coherence can be difficult due to noise.

### SUMMARY

This disclosure relates to injection-locked laser-based beatnote generation that is phase locked to a reference.

In a first embodiment, an apparatus includes a seed laser configured to generate a seed signal and a modulator configured to modulate the seed signal and generate multiple sideband signals. The apparatus also includes multiple injection-locked lasers configured to generate multiple optical signals based on different ones of the sideband signals. The apparatus further includes a combiner configured to combine the optical signals and generate a combined optical signal. In addition, the apparatus includes a feedback loop configured to modify frequencies of the sideband signals generated by the modulator so that the optical signals generated by the injection-locked lasers have a desired frequency difference.

In a second embodiment, a system includes a seed laser configured to generate a seed signal and multiple laser stabilization units configured to generate signals having beatnotes of different frequency spacings. Each laser stabilization unit includes a modulator configured to modulate the seed signal or a sideband of the seed signal and generate multiple sideband signals. Each laser stabilization unit also includes multiple injection-locked lasers configured to generate multiple optical signals based on different ones of the sideband signals. Each laser stabilization unit further includes a combiner configured to combine the optical signals and generate a combined optical signal. In addition, each laser stabilization unit includes a feedback loop configured to modify frequencies of the sideband signals generated by the modulator so that the optical signals generated by the injection-locked lasers have a desired frequency difference.

In a third embodiment, a method includes generating a seed signal and modulating the seed signal to generate multiple sideband signals. The method also includes generating multiple optical signals based on different ones of the sideband signals using multiple injection-locked lasers. The method further includes combining the optical signals to generate a combined optical signal. In addition, the method includes modifying frequencies of the sideband signals based on the combined optical signal so that the optical signals generated by the injection-locked lasers have a desired frequency difference.

Other technical features may be readily apparent to one skilled in the art from the following figures, descriptions, and claims.

### BRIEF DESCRIPTION OF THE DRAWINGS

For a more complete understanding of this disclosure, reference is now made to the following description, taken in conjunction with the accompanying drawings, in which:

FIG. 1 illustrates an example device supporting injection-locked laser-based beatnote generation that is phase locked to a reference according to this disclosure;

FIG. 2 illustrates an example multiple injection-locked laser-based beatnote generator and an example feedback optical phase-locked loop according to this disclosure;

FIG. 3 illustrates an example coherent multi-comb generation system according to this disclosure; and

FIG. 4 illustrates an example method for injection-locked laser-based beatnote generation that is phase locked to a reference according to this disclosure.

### DETAILED DESCRIPTION

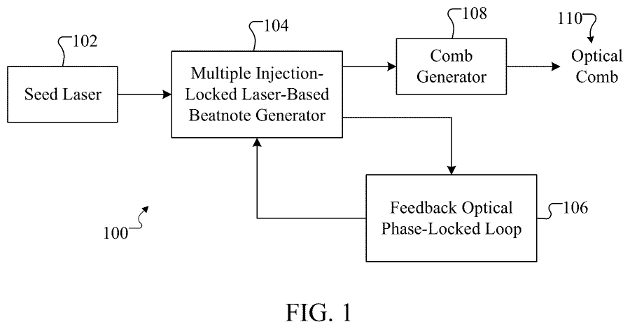

FIGS. 1 through 4, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, various systems rely on optical combs to perform one or more optical functions within the systems. An optical comb refers to a collection of optical signals having a substantially equal separation or other desired separation in terms of frequency. For example, an optical comb may include multiple optical signals that have a spacing of approximately 100 GHz. Optical combs are useful in a number of signal processing applications or other applications, but sustaining optical comb coherence can be difficult due to noise.

In some approaches, multiple injection-locked pump laser sources are injection-locked to a common seed signal, where outputs of the injection-locked pump laser sources are used for parametric optical comb generation. However, phase synchronization between the injection-locked pump laser sources is limited due to noise in the system. Noise sources may be relatively common in a number of systems and may include noise sources that are inherent to optical devices and external noise sources, such as vibrations or thermal gradients that can modulate a refractive index of an optical fiber or optical component.

This disclosure provides various techniques supporting injection-locked laser-based beatnote generation that is phase locked to a reference. As described in more detail below, an optical phase modulator is used to generate multiple sideband signals based on a seed signal, such as a seed signal from a seed laser. The sideband signals are used by injection-locked lasers to generate optical signals having a desired frequency difference. A feedback optical phase-locked loop operates to ensure that the frequency difference between the optical signals generated by the injection-locked lasers is phase-synchronized to a reference signal provided by a reference oscillator. In other words, the feedback optical phase-locked loop operates to lock the frequency difference between the injection-locked lasers to a reference frequency and phase. As a result, the feedback optical phase-locked loop can control operation of the optical phase modulator in order to adjust the generation of the multiple sideband signals and maintain generation of the optical signals having the desired frequency difference. In some cases, the feedback optical phase-locked loop can perform photonic down-conversion prior to photodetection, which can result in the generation of lower-frequency signals. This allows for the use of very high frequency offsets (such as up to 200 GHz or more) between the injection-locked lasers while avoiding the need to use direct photodetection and thus having to rely on expensive photodetectors for very large frequency offsets.

In this way, the described techniques provide for improved coherence between multiple injection-locked lasers. Among other reasons, this is because the reference frequency of the reference oscillator can have very fine stability, and this stability can be impressed upon the frequency difference between the optical signals generated by the injection-locked lasers. Also, the frequency difference between the injection-locked lasers can be controlled by adjusting the injection locking frequency of the lasers simultaneously, as part of the same optical phase-locked loop, which can consolidate injection-locked laser control into a single loop to obtain optimal performance and coherence. Further, at least one optical comb generated using the optical signals can be more stable even in the presence of noise. In some cases, multiple instances of the injection-locked lasers and feedback optical phase-locked loop may be used to produce multiple optical combs, such as when one optical comb is used for modulating data and another optical comb is used as a local oscillator (LO) comb. In these or other cases, the described techniques can allow for improved synchronization between multiple optical combs. Because comb coherence can be improved, the described techniques may also allow for increased processing averaging times, and relaxation of the complexity of coherent phase tracking algorithms (all of which may be implemented in digital signal processors or other components). In addition, providing phase synchronization between the injection-locked lasers and the reference signal can improve linewidth performance of parametric optical comb lines, which can improve sensitivity and reduce spectral corruption in the presence of interferers.

Note that the techniques described in this disclosure may be used in any suitable applications in which one or more optical combs are generated or in which multiple injection-locked lasers are used for beatnote generation or other functions. Example applications here may include coherent optical communication systems, multi-comb spectroscopy systems, optical-based millimeter-wave carrier generation systems, and light detection and ranging (LIDAR) systems. Of course, these example applications are for illustration only, and the techniques described in this disclosure may be used in any other suitable manner. Also note that, in some cases, computer-based or other modeling of the feedback optical phase-locked loop may be performed to determine appropriate phase-locked loop chip and filter parameters to be used for a specific application.

FIG. 1 illustrates an example device 100 supporting injection-locked laser-based beatnote generation that is phase locked to a reference according to this disclosure. As shown in FIG. 1, the device 100 includes a seed laser 102. The seed laser 102 is configured to generate a seed signal, such as a laser signal, having a desired frequency. The seed signal here may have any suitable frequency and any suitable power level. The seed laser 102 represents any suitable optical source configured to generate a laser signal or other seed signal.

The seed signal from the seed laser 102 is provided to a multiple injection-locked laser-based beatnote generator 104. As described in more detail below, the beatnote generator 104 includes a modulator that generates multiple sideband signals based on the seed signal from the seed laser 102. The beatnote generator 104 also includes multiple injection-locked lasers that generate optical output signals having frequencies that match or substantially match the frequencies of selected sideband signals. As a result, the injection-locked lasers generate optical output signals having a frequency difference based on the selected sideband signals. In some embodiments, the optical output signals may have a large frequency difference, such as up to 200 GHz or more. The optical output signals can be combined in order to produce a combined optical signal, which has beatnotes based on the frequency difference between the optical output signals.

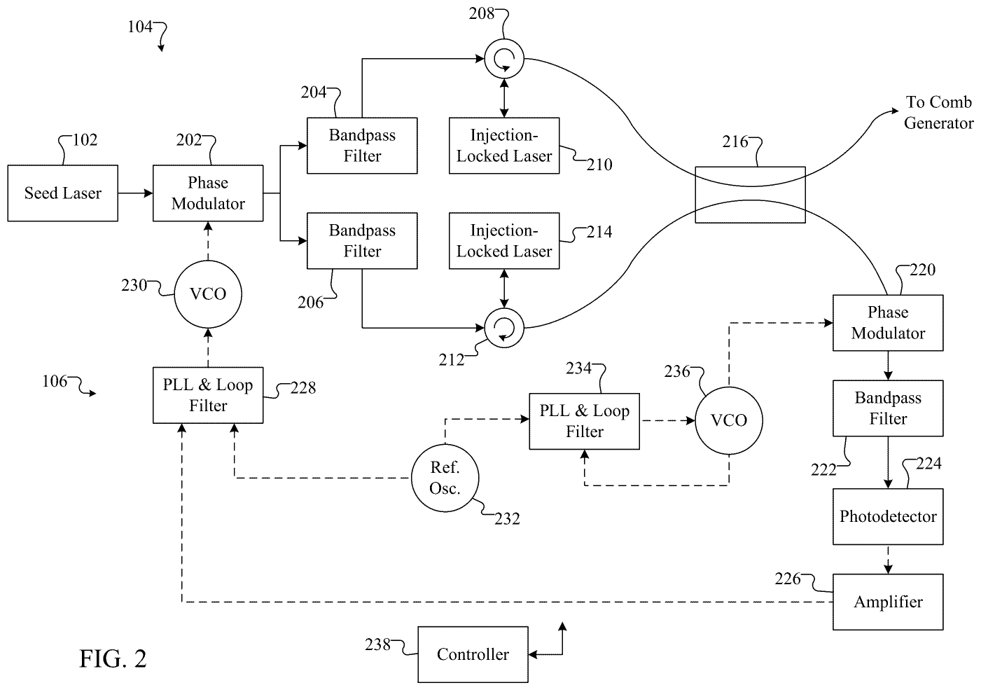

The beatnote generator 104 includes or operates in conjunction with a feedback optical phase-locked loop 106 that processes a first part of the combined optical signal and adjusts the modulator in the beatnote generator 104 so that the optical output signals generated by the injection-locked lasers have a desired frequency difference. The adjustments to the operation of the modulator are based on the use of a reference signal from a reference oscillator. As a result, the beatnote generator 104 is able to generate a combined optical signal having beatnotes that are phase-locked to the reference signal. Example embodiments of the multiple injection-locked laser-based beatnote generator 104 and the feedback optical phase-locked loop 106 are shown in FIG. 2, which is described below.

A second part of the combined optical signal from the beatnote generator 104 in this example is provided to a comb generator 108, which uses the second part of the combined optical signal from the beatnote generator 104 to produce an optical comb 110. The optical comb 110 includes multiple optical signals having a substantially equal separation or other desired separation. The comb generator 108 includes any suitable structure configured to generate an optical comb. In some embodiments, for example, the comb generator 108 may represent or include a parametric mixer that uses the injection-locked pump sources to produce the optical comb 110.

Although FIG. 1 illustrates one example of a device 100 supporting injection-locked laser-based beatnote generation that is phase locked to a reference, various changes may be made to FIG. 1. For example, various components shown in FIG. 1 may be combined, further subdivided, replicated, rearranged, or omitted and additional components may be added according to particular needs. As a particular example, multiple instances of the beatnote generator 104, feedback optical phase-locked loop 106, and comb generator 108 may be used to produce multiple optical combs 110 based on the same seed signal from the seed laser 102. Also, the techniques for injection-locked laser-based beatnote generation that is phase locked to a reference may be used in any other suitable device (whether or not related to comb generation).

FIG. 2 illustrates an example multiple injection-locked laser-based beatnote generator 104 and an example feedback optical phase-locked loop 106 according to this disclosure. As shown in FIG. 2, the beatnote generator 104 includes a phase modulator 202, which receives the seed signal generated by the seed laser 102. The phase modulator 202 operates to modulate the phase of the seed signal based on a signal received from a voltage-controlled oscillator (VCO) 230. During the phase modulation, the phase modulator 202 produces multiple sideband signals based on the seed signal generated by the seed laser 102 and the signal from the VCO 230. For example, assume the VCO 230 provides a signal having a nominal frequency of 25 GHz to the phase modulator 202. Here, the phase modulator 202 may produce sideband signals at ±25 GHz, ±50 GHz, ±75 GHz, ±100 GHz, and so on relative to the frequency of the seed signal. As a result, the phase modulator 202 generates multiple sideband signals at various frequencies. The phase modulator 202 includes any suitable structure configured to perform optical phase modulation and generate sideband signals.

Bandpass filters 204 and 206 filter the sideband signals generated by the phase modulator 202, such as by allowing passage of selected sideband signals within desired frequency ranges and filtering all remaining sideband signals generated by the phase modulator 202. Each bandpass filter 204 and 206 here can be used to filter out any of the sideband signals and allow one or more of the sideband signals to pass. In some embodiments, for example, the bandpass filter 204 may allow passage of the +100 GHz sideband signal while filtering all other sideband signals, and the bandpass filter 206 may allow passage of the −100 GHz sideband signal while filtering all other sideband signals. These embodiments allow for the use of a 200 GHz frequency difference during beatnote generation. However, the bandpass filters 204 and 206 may allow passage of any other suitable sideband signals in order to obtain a desired frequency difference during beatnote generation. Each bandpass filter 204 and 206 includes any suitable structure configured to filter optical signals.

The sideband signal(s) provided by the bandpass filter 204 can be passed through a circulator 208 to a first injection-locked laser 210. The circulator 208 represents a structure that passes an optical signal received at one port to the next port. The first injection-locked laser 210 operates to generate a first optical output signal that is generally frequency-locked to the frequency of the sideband signal(s) provided by the bandpass filter 204. The first injection-locked laser 210 provides the first optical output signal back to the circulator 208, which passes the first optical output signal to a combiner 216. The circulator 208 includes any suitable structure configured to pass optical signals. The first injection-locked laser 210 includes any suitable structure configured to generate an optical signal that is generally frequency-locked to another signal. In some cases, for instance, the first injection-locked laser 210 may include a distributed-feedback (DFB) laser.

Similarly, the sideband signal(s) provided by the bandpass filter 206 can be passed through a circulator 212 to a second injection-locked laser 214. The second injection-locked laser 214 operates to generate a second optical output signal that is generally frequency-locked to the frequency of the sideband signal(s) provided by the bandpass filter 206. The second injection-locked laser 214 provides the second optical output signal back to the circulator 212, which passes the second optical output signal to the combiner 216. The circulator 212 includes any suitable structure configured to pass optical signals. The second injection-locked laser 214 includes any suitable structure configured to generate an optical signal that is generally frequency-locked to another signal. In some cases, for instance, the second injection-locked laser 214 may include a DFB laser.

The combiner 216 receives the optical output signals generated by the injection-locked lasers 210 and 214 and combines the optical output signals to produce a combined optical signal. Because the frequencies of the optical output signals generated by the injection-locked lasers 210 and 214 are different, the resulting combined optical signal has a beatnote frequency that is dependent on the frequency difference between the optical output signals generated by the injection-locked lasers 210 and 214. In this example, the combiner 216 provides part of the combined optical signal to another component, such as the comb generator 108, for use. The combiner 216 also provides another part of the combined optical signal to the feedback optical phase-locked loop 106 for use in controlling the beatnote generator 104. The combiner 216 includes any suitable structure configured to combine optical signals, such as a 2×2 optical coupler or X-coupler.

As shown in FIG. 2, the feedback optical phase-locked loop 106 includes a phase modulator 220, which modulates the portion of the combined optical signal received from the combiner 216. The phase modulator 220 may produce multiple sideband signals based on the portion of the combined optical signal and a signal received from a VCO 236. The resulting modulated signal is filtered using a bandpass filter 222 and detected using a photodetector 224. This supports the photonic down-conversion of the combined optical signal received from the combiner 216 (which may be based on a very large frequency difference) to a more suitable lower frequency. For example, assume the VCO 236 provides a signal having a nominal frequency of 24.2 GHz to the phase modulator 220. Here, if the optical output signals generated by the injection-locked lasers 210 and 214 are 200 GHz apart, the phase modulator 220 may produce modulated signals including sideband signals at 24.2 GHz spacings. The fourth sidebands of the two optical output signals generated by the injection-locked lasers 210 and 214 would have a frequency separation of 6.4 GHz, and the bandpass filter 222 can pass signals at and around that frequency and filter out other frequencies. The phase modulator 220 includes any suitable structure configured to perform optical phase modulation and generate sideband signals. The bandpass filter 222 includes any suitable structure configured to filter optical signals.

The filtered optical signals are provided to the photodetector 224, which operates to sense the filtered optical signals and generate electrical signals corresponding to the optical signals. An amplifier 226 amplifies the resulting electrical signals. The photodetector 224 includes any suitable structure configured to generate electrical signals based on optical signals, such as a photodiode. The amplifier 226 includes any suitable structure configured to amplify electrical signals. The amplified electrical signals are representative of the frequency difference between the optical output signals generated by the injection-locked lasers 210 and 214, and that frequency difference is based on the sideband signals passed by the bandpass filters 204 and 206 to the injection-locked lasers 210 and 214.

The amplified electrical signals are provided to a phase-locked loop (PLL) and loop filter 228, which also receives a reference signal having a reference frequency from a reference oscillator 232. The reference signal can have any suitable reference frequency, such as 100 MHz. The PLL and loop filter 228 operate to adjust the VCO 230 based on frequency and phase differences between the output of the amplifier 226 and the reference signal. As a result, the PLL and loop filter 228 attempt to phase-lock the higher-frequency signal from the amplifier 226 and the lower-frequency signal from the reference oscillator 232 and effectively divides the higher-frequency signal from the amplifier 226 down to a 100 MHz signal. The PLL and loop filter 228 include any suitable structure configured to adjust a VCO based on a reference signal and another signal. The reference oscillator 232 also provides a reference signal (such as a 100 MHz reference signal) to a PLL and loop filter 234, which are coupled to and receive feedback from the VCO 236. The VCO 236 provides an input signal to the phase modulator 220 for use in controlling the modulation performed by the phase modulator 220. The PLL and loop filter 234 help to keep the input signal to the phase modulator 220 at a desired frequency, such as 24.2 GHz.

Each VCO 230 and 236 includes any suitable structure configured to generate a signal having a frequency that can be controlled using an input voltage. The reference oscillator 232 includes any suitable structure configured to provide a reference signal having a desired frequency, and the reference oscillator 232 may represent a highly stable oscillator. The PLL and loop filter 234 include any suitable structure configured to adjust a VCO based on a reference signal and another signal.

In this example, the feedback optical phase-locked loop 106 provides feedback control of the phase modulator 202, which allows for adjustments to be made to the sideband signals generated by the phase modulator 202. Since the injection-locked lasers 210 and 214 are injection-locked to different ones of the sideband signals, this allows for adjustments to be made to the optical output signals generated by the injection-locked lasers 210 and 214 (which are used to produce the optical signal provided to the comb generator 108 or other destination). As a result, the feedback optical phase-locked loop 106 is able to provide feedback control of the phase modulator 202 in order to correct for phase and frequency changes of the beatnote (as contained in the combined optical signal generated by the combiner 216) relative to the reference signal from the reference oscillator 232.

In some embodiments, the multiple injection-locked laser-based beatnote generator 104 and feedback optical phase-locked loop 106 support the use of a static comb line spacing, where the comb line spacing is defined based on the spacing of the sideband signals selected using the bandpass filters 204 and 206 and provided to the injection-locked lasers 210 and 214. Here, the VCO 230 is controlled by the feedback optical phase-locked loop 106 in order to maintain a specified (static) frequency difference between the optical output signals generated by the injection-locked lasers 210 and 214.

In other embodiments, the multiple injection-locked laser-based beatnote generator 104 and feedback optical phase-locked loop 106 support the use of a dynamic comb line spacing. In these embodiments, a controller 238 may be used to adjust operation of one or more of the bandpass filters 204 and 206, the injection-locked lasers 210 and 214, and/or the PLL and loop filter 234. As particular examples, the controller 238 may adjust which sideband frequencies are passed by the bandpass filters 204 and 206, how the injection-locked lasers 210 and 214 operate, and/or which frequency is provided by the PLL and loop filter 234 to the phase modulator 220. One, some, or all of these characteristics may be controlled in order to alter the frequency difference between the optical output signals generated by the injection-locked lasers 210 and 214, which affects the spacing of the optical signals in the optical comb 110. The controller 238 includes any suitable structure configured to control one or more operational characteristics, such as one or more microprocessors, microcontrollers, digital signal processors (DSPs), application-specific integrated circuits (ASICs), field programmable gate arrays (FPGAs), or discrete components.

Note that connections shown in FIG. 2 include connections shown in solid lines and connections shown in dashed lines. The connections shown in solid lines represent connections in which optical signals are transported between components, and these connections may be formed using optical fibers or other optical waveguides configured to transport optical signals. The connections shown in dashed lines represent connections in which electrical signals are transported between components, and these connections may be formed using copper or other conductive electrical traces or other electrical pathways configured to transport electrical signals.

Although FIG. 2 illustrates one example of a multiple injection-locked laser-based beatnote generator 104 and one example of a feedback optical phase-locked loop 106, various changes may be made to FIG. 2. For example, various components shown in FIG. 2 may be combined, further subdivided, replicated, rearranged, or omitted and additional components may be added according to particular needs.

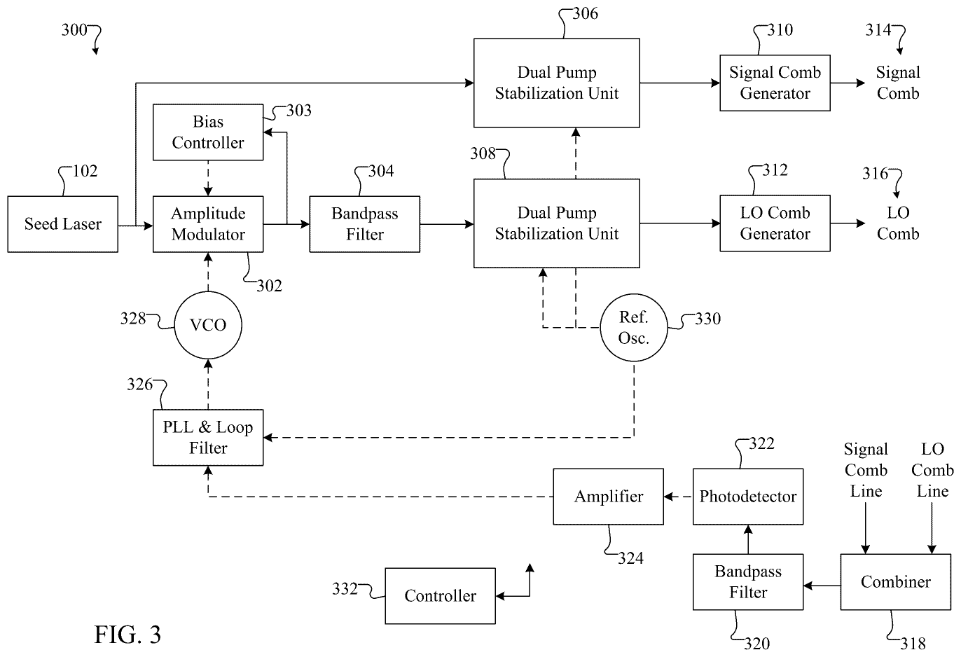

FIG. 3 illustrates an example coherent multi-comb generation system 300 according to this disclosure. As shown in FIG. 3, the multi-comb generation system 300 includes the seed laser 102, which provides a seed signal to an amplitude modulator 302. The amplitude modulator 302, which is biased appropriately using a bias controller 303, operates to modulate the seed signal based on a signal received from a VCO 328 and generate sideband signals. For example, the bias controller 303 can bias the amplitude modulator 302 so that the amplitude modulator 302 strongly attenuates the seed signal at its original frequency and generates sidebands. A bandpass filter 304 filters the modulated seed signal, such as by limiting the modulated seed signal to a narrower frequency range associated with a specified sideband signal. The specific sideband signal that is selected can be chosen to achieve a desired frequency offset between two comb signals to be generated. The amplitude modulator 302 includes any suitable structure configured to perform optical modulation and generate sideband signals. The bias controller 303 includes any suitable structure configured to change the bias of an amplitude modulator 302. The bandpass filter 304 includes any suitable structure configured to filter optical signals.

In this example, the seed signal is provided to a first dual pump stabilization unit 306, and the filtered sideband of the seed signal is provided to a second dual pump stabilization unit 308. Each dual pump stabilization unit 306 and 308 may be implemented as shown in FIG. 2. For example, each dual pump stabilization unit 306 and 308 may include the components 202-230, 234-236 as shown in FIG. 2. Rather than each dual pump stabilization unit 306 and 308 having its own reference oscillator 232, a reference oscillator 330 can be shared between the dual pump stabilization units 306 and 308. Thus, one or more reference signals from the reference oscillator 330 may be used in place of the one or more reference signals from the reference oscillator 232 in each seed laser stabilization unit 306 and 308.

Each of the dual pump stabilization units 306 and 308 produces an optical signal that is provided to a corresponding comb generator 310 and 312. Each comb generator 310 and 312 can use the optical signal from the corresponding dual pump stabilization unit 306 and 308 to generate an optical comb 314 and 316. In this particular example, the comb generator 310 is said to represent a signal comb generator and is used to generate a signal comb 314, which may represent a collection of optical signals at different frequencies that are modulated to encode data onto the optical signals. Also, the comb generator 312 is said to represent a local oscillator (LO) comb generator and is used to generate an LO comb 316, which may represent a collection of optical signals at different frequencies that are used to demodulate the data encoded onto the optical signals of the signal comb 314. Note, however, that the optical combs produced here may be used for any suitable purpose(s) and are not limited to this specific example. In some embodiments, the optical combs 314 and 316 can be generated having different frequency spacings. For instance, the first dual pump stabilization unit 306 may include injection-locked lasers that have a frequency spacing of 200 GHz, and the second dual pump stabilization unit 308 may include injection-locked lasers that have a frequency spacing of 193.6 GHz.

To provide feedback control during generation of both optical combs here, a combiner 318 may be used to combine at least one of the optical signals from the optical comb 314 and at least one of the optical signals from the optical comb 316. The resulting signal is filtered using a bandpass filter 320, the filtered signal is detected by a photodetector 322, and an amplifier 324 amplifies the resulting electrical signal. A PLL and loop filter 326 can be used to adjust the VCO 328 based on the amplified signal from the amplifier 324 and a reference signal from the reference oscillator 330.

The combiner 318 includes any suitable structure configured to combine optical signals. The bandpass filter 320 includes any suitable structure configured to filter optical signals. The photodetector 322 includes any suitable structure configured to generate electrical signals based on optical signals, such as a photodiode. The amplifier 324 includes any suitable structure configured to amplify electrical signals. The PLL and loop filter 326 include any suitable structure configured to adjust a VCO based on a reference signal and another signal. The VCO 328 includes any suitable structure configured to generate a signal having a frequency that can be controlled using an input voltage. The reference oscillator 330 includes any suitable structure configured to provide a reference signal having a desired frequency, and the reference oscillator 330 may represent a highly stable oscillator.

In some embodiments, the multi-comb generation system 300 supports the use of static comb line spacings. Here, each dual pump stabilization unit 306 and 308 may be controlled in order to maintain specified (static) frequency differences between the optical output signals generated by the injection-locked lasers in each dual pump stabilization unit 306 and 308. In other embodiments, a controller 332 may be used to adjust operation of one or more components in each of the dual pump stabilization units 306 and 308 (such as in the same or similar manner discussed above with reference to FIG. 2) in order to support the use of a dynamic comb line spacing with each dual pump stabilization unit 306 and 308. The controller 332 may also or alternatively control the operation of the PLL and loop filter 326 in order to support the use of a dynamic offset between the optical combs 314 and 316. The controller 332 includes any suitable structure configured to control one or more aspects of the system 300, such as one or more microprocessors, microcontrollers, DSPs, ASICs, FPGAs, or discrete components.

Note that the PLL and loop filter 326 used with the VCO 328 and the amplitude modulator 302 may act to keep the seeds for the stabilization units 306 and 308 at a desired offset from one another. This can be similar to the PLL and loop filter 228, which act to keep the seeds for the injection-locked lasers 210 and 214 at a desired offset from one another. One possible difference between the PLL and loop filters 228 and 326 is that photonic down-conversion may not be needed with the PLL and loop filter 326 (although it could be used). This is because the optical signals from the optical combs 314 and 316 provided to the combiner 318 may be fairly close together in frequency. That is, while each individual optical comb 314 and 316 can have large comb line spacings between its own comb lines, the separation between a comb line of the optical comb 314 and a comb line of the optical comb 316 need not be large. Similar to the PLL and loop filter 228, the PLL and loop filter 326 use the beatnote generated by two comb lines from different optical combs 314 and 316. As the beatnote from these comb lines deviates from a reference, the PLL and loop filter 326 make corrections by modulating the sidebands generated by the amplitude modulator 302 to lock the frequency and phase to a reference.

Although FIG. 3 illustrates one example of a coherent multi-comb generation system 300, various changes may be made to FIG. 3. For example, various components shown in FIG. 3 may be combined, further subdivided, replicated, rearranged, or omitted and additional components may be added according to particular needs.

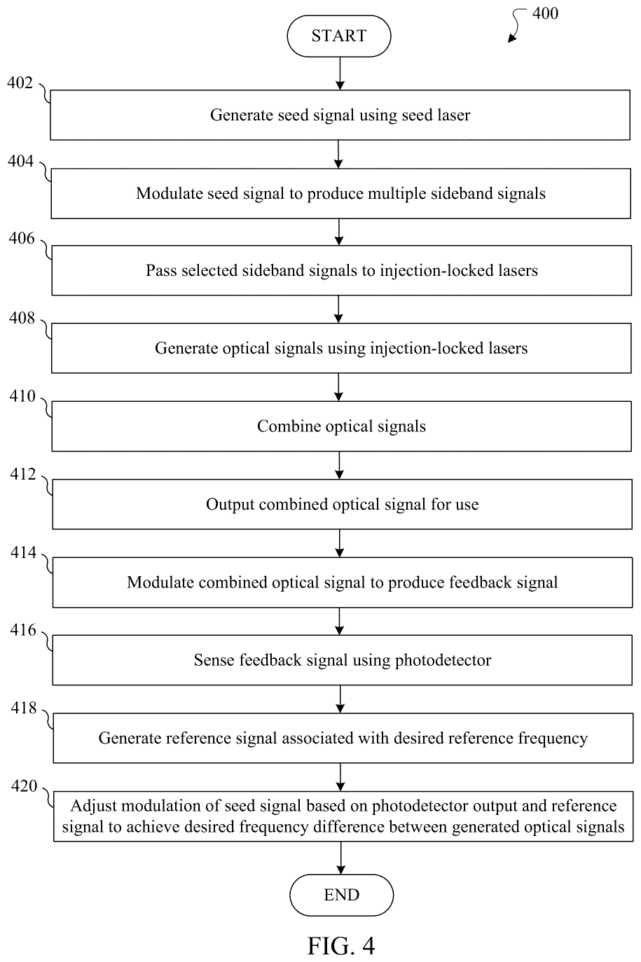

FIG. 4 illustrates an example method 400 for injection-locked laser-based beatnote generation that is phase locked to a reference according to this disclosure. For ease of explanation, the method 400 is described as being performed by the device 100 shown in FIG. 1, where the device 100 includes the multiple injection-locked laser-based beatnote generator 104 and the feedback optical phase-locked loop 106 shown in FIG. 2. However, the method 400 may be performed using any other suitable device or system, such as the system 300.

As shown in FIG. 4, a seed signal is generated using a seed laser at step 402. This may include, for example, using the seed laser 102 to generate a seed signal having one or more specified wavelengths or one or more wavelengths within a specified wavelength range. The seed signal is modulated to produce multiple sideband signals at step 404. This may include, for example, using the phase modulator 202 to modulate the seed signal based on a signal from the VCO 230. This may also include the phase modulator 202 producing multiple sideband signals, such as sideband signals at ±25 GHz, ±50 GHz, ±75 GHz, ±100 GHz, etc. relative to the frequency of the seed signal (assuming the VCO 230 produces a signal having a nominal frequency of 25 GHz).

Selected sideband signals are passed to injection-locked lasers at step 406. This may include, for example, using the bandpass filters 204 and 206 to pass sideband signals within specified frequency bands to the injection-locked lasers 210 and 214. As a particular example, this may include using the bandpass filters 204 and 206 to pass the ±100 GHz sideband signals to the injection-locked lasers 210 and 214. Optical signals are generated using the injection-locked lasers at step 408. This may include, for example, using the injection-locked lasers 210 and 214 to generate optical output signals that are frequency-locked to the selected sideband signals. The optical signals are combined at step 410. This may include, for example, using the combiner 216 to combine the optical output signals and generate a combined optical signal. The combined optical signal is output for use at step 412. This may include, for example, using the combiner 216 to split the combined optical signal. This may also include providing a portion of the combined optical signal to the comb generator 108 for use in generating an optical comb 110. Note, however, that the combined optical signal may be used in any other suitable manner.

Modulation of the combined optical signal is performed to generate a feedback optical signal at step 414. This may include, for example, providing another portion of the combined optical signal to the phase modulator 220, which also receives a signal from the VCO 236. This may also include the phase modulator 220 modulating the other portion of the combined optical signal and generating one or more sideband signals at one or more frequencies. The feedback optical signal is detected using a photodetector at step 416. This may include, for example, using the photodetector 224 to convert the feedback optical signal into an electrical signal after being filtered using the bandpass filter 222. A reference signal associated with a desired reference frequency is generated at step 418. This may include, for example, using the reference oscillator 232 to generate a reference signal having a nominal frequency of 100 MHz. The modulation of the seed signal is adjusted based on the photodetector output and the reference signal to achieve a desired frequency difference between the optical signals generated by the injection-locked lasers at step 420. This may include, for example, using the PLL and loop filter 228 to control the VCO 230 and adjust the frequency of the signal provided by the VCO 230 to the phase modulator 202. This adjusts how the phase modulator 202 generates the sideband signals, which thereby adjusts the frequencies of the optical output signals generated by the injection-locked lasers 210 and 214.

Although FIG. 4 illustrates one example of a method 400 for injection-locked laser-based beatnote generation that is phase locked to a reference, various changes may be made to FIG. 4. For example, while shown as a series of steps, various steps in FIG. 4 may overlap, occur in parallel, occur in a different order, or occur any number of times.

Note that while the description above has provided specific numerical values for different features of devices and systems described above, these numerical values are examples only. For instance, the description above has provided specific numerical values for frequencies related to sideband signals, frequency differences, down-conversion frequencies, and reference frequencies. However, these numerical values are for illustration and explanation only and do not limit the scope of this disclosure to those specific sideband signals, frequency differences, down-conversion frequencies, and reference frequencies. Moreover, the specific numerical values given above are approximate values only and can vary based on various factors, such as manufacturing tolerances and environmental conditions.

The following describes example embodiments of this disclosure that implement or relate to injection-locked laser-based beatnote generation that is phase locked to a reference. However, other embodiments may be used in accordance with the teachings of this disclosure.

In a first embodiment, an apparatus includes a seed laser configured to generate a seed signal and a modulator configured to modulate the seed signal and generate multiple sideband signals. The apparatus also includes multiple injection-locked lasers configured to generate multiple optical signals based on different ones of the sideband signals. The apparatus further includes a combiner configured to combine the optical signals and generate a combined optical signal. In addition, the apparatus includes a feedback loop configured to modify frequencies of the sideband signals generated by the modulator so that the optical signals generated by the injection-locked lasers have a desired frequency difference.

Any single one or any suitable combination of the following features may be used with the first embodiment. The feedback loop may be configured to perform photonic down-conversion of a portion of the combined optical signal prior to photodetection in order to decrease a frequency of a signal that undergoes photodetection. The feedback loop may include a first VCO configured to generate a signal provided to the modulator for use in modulating the seed signal, a reference oscillator configured to generate a reference signal, and a phase-locked loop and loop filter configured to modify a frequency of the signal generated by the first VCO based on the reference signal and a portion of the combined optical signal received by the feedback loop. The feedback loop may also include a second modulator configured to modulate the portion of the combined optical signal and generate a lower-frequency optical signal, a second VCO configured to generate a signal provided to the second modulator for use in modulating the portion of the combined optical signal, and a phase-locked loop configured to modify a frequency of the signal generated by the second VCO based on the reference signal. The feedback loop may further include a filter configured to filter the lower-frequency optical signal, a photodetector configured to sense the filtered lower-frequency optical signal, and an amplifier configured to amplify an output of the photodetector (where an output of the amplifier is coupled to the phase-locked loop and loop filter). The apparatus may include a controller configured to adjust one or more components of the apparatus in order to obtain a tunable frequency difference between the optical signals generated by the injection-locked lasers. The apparatus may include a comb generator configured to generate an optical comb based on the combined optical signal. The desired frequency difference of the optical signals generated by the injection-locked lasers may be about 200 GHz or more, although in other cases the desired frequency difference of the optical signals generated by the injection-locked lasers may be less than about 200 GHz.

In a second embodiment, a system includes a seed laser configured to generate a seed signal and multiple laser stabilization units configured to generate signals having beatnotes of different frequency spacings. Each laser stabilization unit includes a modulator configured to modulate the seed signal or a sideband of the seed signal and generate multiple sideband signals. Each laser stabilization unit also includes multiple injection-locked lasers configured to generate multiple optical signals based on different ones of the sideband signals. Each laser stabilization unit further includes a combiner configured to combine the optical signals and generate a combined optical signal. In addition, each laser stabilization unit includes a feedback loop configured to modify frequencies of the sideband signals generated by the modulator so that the optical signals generated by the injection-locked lasers have a desired frequency difference.

Any single one or any suitable combination of the following features may be used with the second embodiment. In each laser stabilization unit, the feedback loop may be configured to perform photonic down-conversion of a portion of the combined optical signal prior to photodetection in order to decrease a frequency of a signal that undergoes photodetection. The system may include a reference oscillator configured to generate a reference signal. In each laser stabilization unit, the feedback loop may include a first VCO configured to generate a signal provided to the modulator for use in modulating the seed signal or the sideband of the seed signal and a phase-locked loop and loop filter configured to modify a frequency of the signal generated by the first VCO based on the reference signal and a portion of the combined optical signal received by the feedback loop. In each laser stabilization unit, the feedback loop may also include a second modulator configured to modulate the portion of the combined optical signal and generate a lower-frequency optical signal, a second VCO configured to generate a signal provided to the second modulator for use in modulating the portion of the combined optical signal, and a phase-locked loop configured to modify a frequency of the signal generated by the second VCO based on the reference signal. In each laser stabilization unit, the feedback loop may further include a filter configured to filter the lower-frequency optical signal, a photodetector configured to sense the filtered lower-frequency optical signal, and an amplifier configured to amplify an output of the photodetector (where an output of the amplifier is coupled to the phase-locked loop and loop filter). The system may include a controller configured to adjust one or more components of the system in order to obtain at least one of (i) a tunable frequency difference between the optical signals generated by the injection-locked lasers in each laser stabilization unit and (ii) a tunable offset between optical combs generated using the signals having the beatnotes of the different frequency spacings. The system may include multiple comb generators configured to generate multiple optical combs based on the signals having the beatnotes of the different frequency spacings. The system may include an amplitude modulator configured to modulate the seed signal and generate a sideband of the seed signal (where a first of the laser stabilization units is configured to receive the seed signal and a second of the laser stabilization units is configured to receive the sideband of the seed signal), a VCO configured to generate a signal provided to the amplitude modulator for use in modulating the seed signal, and a phase-locked loop and loop filter configured to modify a frequency of the signal generated by the VCO. The system may include a second combiner configured to combine at least one optical signal from each of the optical combs to produce a second combined optical signal, a filter configured to filter the second combined optical signal, a photodetector configured to sense the filtered second combined optical signal, and an amplifier configured to amplify an output of the photodetector (where an output of the amplifier is coupled to the phase-locked loop and loop filter). The laser stabilization units may be offset in frequency based on the sideband of the seed signal.

In a third embodiment, a method includes generating a seed signal and modulating the seed signal to generate multiple sideband signals. The method also includes generating multiple optical signals based on different ones of the sideband signals using multiple injection-locked lasers. The method further includes combining the optical signals to generate a combined optical signal. In addition, the method includes modifying frequencies of the sideband signals based on the combined optical signal so that the optical signals generated by the injection-locked lasers have a desired frequency difference.

Any single one or any suitable combination of the following features may be used with the third embodiment. Modifying the frequencies of the sideband signals may include generating a reference signal, performing photonic down-conversion of a portion of the combined optical signal to generate a lower-frequency optical signal, performing photodetection to sense the lower-frequency optical signal, and modifying a frequency of a signal used to modulate the seed signal based on the reference signal and results of the photodetection.

In some embodiments, various functions described in this patent document are implemented or supported by a computer program that is formed from computer readable program code and that is embodied in a computer readable medium. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive (HDD), a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable storage device.

It may be advantageous to set forth definitions of certain words and phrases used throughout this patent document. The terms “application” and “program” refer to one or more computer programs, software components, sets of instructions, procedures, functions, objects, classes, instances, related data, or a portion thereof adapted for implementation in a suitable computer code (including source code, object code, or executable code). The term “communicate,” as well as derivatives thereof, encompasses both direct and indirect communication. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus comprising:
a seed laser configured to generate a seed signal;
a modulator configured to modulate the seed signal and generate multiple sideband signals;
multiple injection-locked lasers configured to generate multiple optical signals based on different ones of the sideband signals;
a combiner configured to combine the optical signals and generate a combined optical signal; and
a feedback loop configured to modify frequencies of the sideband signals generated by the modulator so that the optical signals generated by the injection-locked lasers have a desired frequency difference.

2. The apparatus of claim 1, wherein the feedback loop is configured to perform photonic down-conversion of a portion of the combined optical signal prior to photodetection in order to decrease a frequency of a signal that undergoes photodetection.

3. The apparatus of claim 1, wherein the feedback loop comprises:
a first voltage-controlled oscillator (VCO) configured to generate a signal provided to the modulator for use in modulating the seed signal;
a reference oscillator configured to generate a reference signal; and
a phase-locked loop and loop filter configured to modify a frequency of the signal generated by the first VCO based on the reference signal and a portion of the combined optical signal received by the feedback loop.

4. The apparatus of claim 3, wherein the feedback loop further comprises:
a second modulator configured to modulate the portion of the combined optical signal and generate a lower-frequency optical signal;
a second VCO configured to generate a signal provided to the second modulator for use in modulating the portion of the combined optical signal, and
a phase-locked loop configured to modify a frequency of the signal generated by the second VCO based on the reference signal.

5. The apparatus of claim 4, wherein the feedback loop further comprises:
a filter configured to filter the lower-frequency optical signal;
a photodetector configured to sense the filtered lower-frequency optical signal; and
an amplifier configured to amplify an output of the photodetector, an output of the amplifier coupled to the phase-locked loop and loop filter.

6. The apparatus of claim 1, further comprising:
a controller configured to adjust one or more components of the apparatus in order to obtain a tunable frequency difference between the optical signals generated by the injection-locked lasers.

7. The apparatus of claim 1, further comprising:
a comb generator configured to generate an optical comb based on the combined optical signal.

8. The apparatus of claim 1, wherein the desired frequency difference of the optical signals generated by the injection-locked lasers is about 200 GHz or more.

9. A system comprising:
a seed laser configured to generate a seed signal; and
multiple laser stabilization units configured to generate signals having beatnotes of different frequency spacings, each laser stabilization unit comprising:
a modulator configured to modulate the seed signal or a sideband of the seed signal and generate multiple sideband signals;
multiple injection-locked lasers configured to generate multiple optical signals based on different ones of the sideband signals;
a combiner configured to combine the optical signals and generate a combined optical signal; and
a feedback loop configured to modify frequencies of the sideband signals generated by the modulator so that the optical signals generated by the injection-locked lasers have a desired frequency difference.

10. The system of claim 9, wherein, in each laser stabilization unit, the feedback loop is configured to perform photonic down-conversion of a portion of the combined optical signal prior to photodetection in order to decrease a frequency of a signal that undergoes photodetection.

11. The system of claim 9, further comprising:
a reference oscillator configured to generate a reference signal;
wherein, in each laser stabilization unit, the feedback loop comprises:
a first voltage-controlled oscillator (VCO) configured to generate a signal provided to the modulator for use in modulating the seed signal or the sideband of the seed signal; and
a phase-locked loop and loop filter configured to modify a frequency of the signal generated by the first VCO based on the reference signal and a portion of the combined optical signal received by the feedback loop.

12. The system of claim 11, wherein, in each laser stabilization unit, the feedback loop further comprises:
a second modulator configured to modulate the portion of the combined optical signal and generate a lower-frequency optical signal;
a second VCO configured to generate a signal provided to the second modulator for use in modulating the portion of the combined optical signal; and
a phase-locked loop configured to modify a frequency of the signal generated by the second VCO based on the reference signal.

13. The system of claim 12, wherein, in each laser stabilization unit, the feedback loop further comprises:
a filter configured to filter the lower-frequency optical signal;
a photodetector configured to sense the filtered lower-frequency optical signal; and
an amplifier configured to amplify an output of the photodetector, an output of the amplifier coupled to the phase-locked loop and loop filter.

14. The system of claim 9, further comprising:
a controller configured to adjust one or more components of the system in order to obtain at least one of:
a tunable frequency difference between the optical signals generated by the injection-locked lasers in each laser stabilization unit; and
a tunable offset between optical combs generated using the signals having the beatnotes of the different frequency spacings.

15. The system of claim 9, further comprising:
multiple comb generators configured to generate multiple optical combs based on the signals having the beatnotes of the different frequency spacings.

16. The system of claim 15, further comprising:
an amplitude modulator configured to modulate the seed signal and generate a sideband of the seed signal, wherein a first of the laser stabilization units is configured to receive the seed signal and a second of the laser stabilization units is configured to receive the sideband of the seed signal;
a voltage-controlled oscillator (VCO) configured to generate a signal provided to the amplitude modulator for use in modulating the seed signal; and
a phase-locked loop and loop filter configured to modify a frequency of the signal generated by the VCO.

17. The system of claim 16, further comprising:
a second combiner configured to combine at least one optical signal from each of the optical combs to produce a second combined optical signal;
a filter configured to filter the second combined optical signal;
a photodetector configured to sense the filtered second combined optical signal; and
an amplifier configured to amplify an output of the photodetector, an output of the amplifier coupled to the phase-locked loop and loop filter.

18. The system of claim 9, wherein the laser stabilization units are offset in frequency based on the sideband of the seed signal.

19. A method comprising:
generating a seed signal;
modulating the seed signal to generate multiple sideband signals;
generating multiple optical signals based on different ones of the sideband signals using multiple injection-locked lasers;
combining the optical signals to generate a combined optical signal; and
modifying frequencies of the sideband signals based on the combined optical signal so that the optical signals generated by the injection-locked lasers have a desired frequency difference.

20. The method of claim 19, wherein modifying the frequencies of the sideband signals comprises:
generating a reference signal;
performing photonic down-conversion of a portion of the combined optical signal to generate a lower-frequency optical signal;
performing photodetection to sense the lower-frequency optical signal; and
modifying a frequency of a signal used to modulate the seed signal based on the reference signal and results of the photodetection.
